(19) United States
(12) Patent Application Publication
(10) Pub. No.: US 2026/0282705 A1
(43) Pub. Date: Sep. 17, 2026

(54) DISPLAY DEVICE AND ELECTRONIC DEVICE INCLUDING THE SAME

(71) Applicant: Samsung Display Co., Ltd., Yongin-Si (KR)

(72) Inventors: Kwangsoo Lee, Yongin-si (KR); Kiwook Kim, Yongin-si (KR); Hyunchol Bang, Yongin-si (KR); Sojung Yoon, Yongin-si (KR); Seungjae Lee, Yongin-si (KR)

(21) Appl. No.: 19/262,227

(22) Filed: Jul. 8, 2025

(30) Foreign Application Priority Data
Mar. 13, 2025 (KR) 10-2025-0032936

(51) Int. Cl. H10K 59/80; H10K 59/131

(52) U.S. Cl. CPC H10K 59/8722; H10K 59/131

(57) ABSTRACT

A display device includes a first substrate including a display area and a peripheral area, a thin film transistor disposed on the first substrate in the display area and including a semiconductor layer and a gate electrode, a first metal layer disposed on the first substrate in the peripheral area, a first interlayer insulating film covering the gate electrode and the first metal layer, a second metal layer disposed on the first interlayer insulating film so as to overlap the first metal layer, an inorganic protective layer disposed on the first interlayer insulating film so as to cover an end portion of the second metal layer and including a first opening exposing a portion of the second metal layer, and a sealing member disposed on the inorganic protective layer so as to overlap the first opening.

### CROSS-REFERENCE TO RELATED APPLICATION

This application is based on and claims priority under 35 USC § 119 to Korean Patent Application No. 10-2025-0032936, filed on Mar. 13, 2025, in the Korean Intellectual Property Office, the disclosure of which is incorporated by reference herein in its entirety.

### BACKGROUND

### 1. Field

One or more embodiments relate to a device, and, more particularly, to a display device and an electronic device including the same.

### 2. Description of the Related Art

Mobility-based electronic devices are widely used. As mobile electronic devices, not only compact electronic devices such as mobile phones but also tablet personal computers (PCs) have recently become widely used.

To support various functions, such mobile electronic devices include a display device to provide users with visual information such as images or videos. Recently, as other components for driving a display device are miniaturized, the proportion occupied by the display device in an electronic device has been gradually increased, and structures to enable bending of the display device from a flat state to a certain angle are under development.

### SUMMARY

One or more embodiments include a display device in which damage to metal layers disposed in a peripheral area is reduced and a bonding strength of a sealing member bonding two substrates is improved.

However, such an objective is an example, and objectives to be solved by the disclosure are not limited thereto.

Additional aspects will be set forth in part in the description which follows and, in part, will be apparent from the description, or may be learned by practice of the presented embodiments of the disclosure.

According to one or more embodiments, a display device includes a first substrate including a display area and a peripheral area, a thin film transistor disposed on the first substrate in the display area, and including a semiconductor layer and a gate electrode, a first metal layer disposed on the first substrate in the peripheral area, a first interlayer insulating film covering the gate electrode and the first metal layer, a second metal layer disposed on the first interlayer insulating film so as to overlap the first metal layer, an inorganic protective layer disposed on the first interlayer insulating film so as to cover an end portion of the second metal layer, and including a first opening exposing a portion of the second metal layer, a sealing member disposed on the inorganic protective layer so as to overlap the first opening.

In an embodiment, the first metal layer may include a first-1 metal layer portion that overlaps the second metal layer, and a first-2 metal layer portion that does not overlap the second metal layer, and the first-2 metal layer portion overlaps the inorganic protective layer.

In an embodiment, the sealing member may be in direct contact with the second metal layer.

In an embodiment, the second metal layer may be sealed by the inorganic protective layer and the sealing member.

In an embodiment, the display device may further include an organic light-emitting element including a pixel electrode disposed on the inorganic protective layer so as to overlap the display area and electrically connected with the thin film transistor, an intermediate layer disposed on the pixel electrode, and a counter electrode disposed on the intermediate layer, and a third metal layer disposed on the inorganic protective layer and electrically connecting the counter electrode with the second metal layer.

In an embodiment, the inorganic protective layer further may include a first contact hole that is spaced apart from the first opening and exposes a portion of the second metal layer, and the third metal layer may be in contact with the second metal layer through the first contact hole.

In an embodiment, the display device may further include a fourth metal layer disposed on the inorganic protective layer, at least a portion of which is accommodated in the first opening and in contact with the second metal layer.

In an embodiment, the sealing member may be in direct contact with the fourth metal layer.

In an embodiment, the display device may further include an organic insulating layer disposed between the inorganic protective layer and the counter electrode, wherein the organic insulating layer may be spaced apart from the second metal layer.

In an embodiment, the first metal layer and the gate electrode may be disposed in a same layer and include a same material.

According to one or more embodiments, an electronic device includes a first substrate including a display area and a peripheral area, a thin film transistor disposed on the first substrate in the display area, and including a semiconductor layer and a gate electrode, a first metal layer disposed on the first substrate in the peripheral area, a first interlayer insulating film covering the gate electrode and the first metal layer, a second metal layer disposed on the first interlayer insulating film so as to overlap the first metal layer, an inorganic protective layer disposed on the first interlayer insulating film and including a first opening exposing a portion of the second metal layer, a sealing member disposed on the inorganic protective layer so as to overlap the first opening, wherein the first metal layer includes a first-1 metal layer portion that overlaps the second metal layer and a first-2 metal layer portion that does not overlap the second metal layer, and the first-2 metal layer portion overlaps the inorganic protective layer.

In an embodiment, the inorganic protective layer may cover an end portion of the second metal layer.

In an embodiment, the sealing member may be in direct contact with the second metal layer.

In an embodiment, the second metal layer may be sealed by the inorganic protective layer and the sealing member.

In an embodiment, the electronic device may father include an organic light-emitting element including a pixel electrode disposed on the inorganic protective layer so as to overlap the display area and electrically connected with the thin film transistor, an intermediate layer disposed on the pixel electrode, and a counter electrode disposed on the intermediate layer, and a third metal layer disposed on the inorganic protective layer and electrically connecting the counter electrode with the second metal layer.

In an embodiment, the inorganic protective layer may further include a first contact hole that is spaced apart from the first opening and exposes a portion of the second metal layer, and the third metal layer may contact the second metal layer through the first contact hole.

In an embodiment, the electronic device may father include a fourth metal layer disposed on the inorganic protective layer, at least a portion of which is accommodated in the first opening and in contact with the second metal layer.

In an embodiment, the sealing member may be in direct contact with the fourth metal layer.

In an embodiment, the electronic device may further include an organic insulating layer disposed between the inorganic protective layer and the counter electrode, wherein the organic insulating layer may be spaced apart from the second metal layer.

In an embodiment, the first metal layer and the gate electrode may be disposed in a same layer and include a same material.

Other aspects, features, and advantages of the disclosure will become more apparent from the drawings, the claims, and the detailed description.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display device according to an embodiment;

FIG. 2 is a plan view schematically illustrating the display device according to an embodiment;

FIGS. 3 and 4 are equivalent circuit diagrams of a pixel that may be included in the display device according to an embodiment;

FIGS. 5 and 6 are cross-sectional views schematically illustrating a portion of the display device according to an embodiment;

FIG. 7 is a cross-sectional view schematically illustrating a portion of the display device according to an embodiment;

FIG. 8 is a block diagram of an electronic device according to an embodiment; and

FIG. 9 is a perspective view schematically illustrating an electronic device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “including” and “having” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another or may represent different directions that are not perpendicular to one another.

When a certain embodiment may be implemented differently, a specific process order may be different from the described order. For example, two consecutively described processes may be performed substantially at the same time or may be performed in an order opposite to the described order.

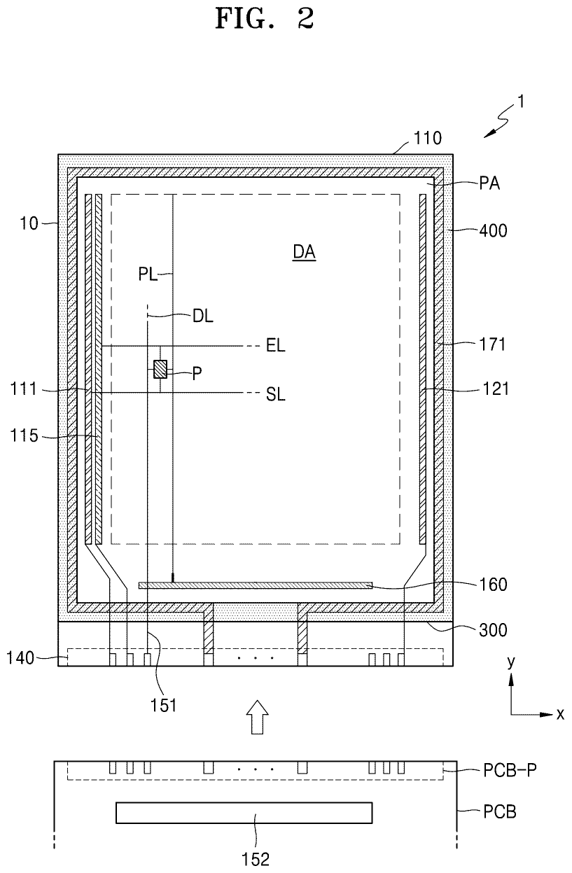

In the specification, an expression “in a plan view” means a plane viewed from a direction perpendicular to a first substrate 110 (see FIG. 2). That is, “A and B spaced apart from each other in a plan view” means “A and B spaced apart from each other when viewed in a direction perpendicular to the first substrate 110 (see FIG. 2).”

In this specification, “in a cross section” means a plane cut in a direction perpendicular to the first substrate 110 (see FIG. 2). That is, “A and B are spaced apart from each other in a cross-section” means “A and B are spaced apart from each other in a plane cut in the direction perpendicular to the first substrate 110 (see FIG. 2).”

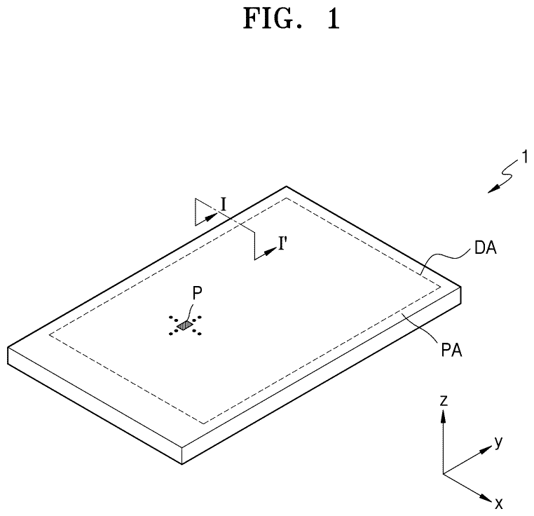

FIG. 1 is a perspective view schematically illustrating a display device 1 according to an embodiment.

Referring to FIG. 1, the display device 1 includes a display area DA that displays an image and a peripheral area PA that does not display the image. A peripheral area PA may be disposed surrounding the display area DA. The display device 1 may provide the image to the outside using light emitted from the display area DA.

FIG. 1 illustrates the display area DA of the display device 1 as being rectangular, but the disclosure is not limited thereto. The shape of the display area DA may be a circle, an ellipse, or a polygon such as a triangle or a pentagon. In addition, the display device 1 of FIG. 1 illustrates a flat-type flat display device, but it is obvious that the display device 1 may be implemented in any one of various forms such as flexible, foldable, or rollable display devices.

In the following description, an organic light-emitting display device is described as an example of the display device 1 according to an embodiment, but the display device 1 is not limited thereto. In another embodiment, the display device 1 may include an inorganic light-emitting display device, an inorganic electroluminescent (EL) display device, or a quantum-dot light-emitting display device. For example, an emission layer of a display element provided in the display device 1 may include an organic material, an inorganic material, quantum dots, a combination of an organic material and quantum dots, or a combination of an inorganic material and quantum dots.

FIG. 2 is a plan view schematically illustrating the display device 1 according to an embodiment.

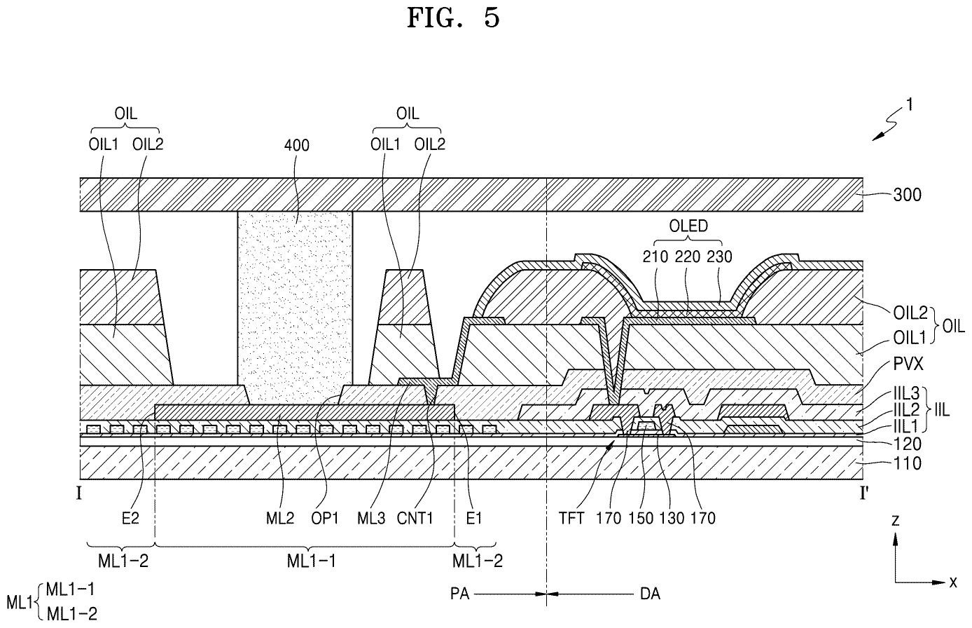

Referring to FIG. 2, the display device 1 includes a display panel 10. A plurality of pixels P are disposed in the display area DA of the first substrate 110. Each of the plurality of pixels P may include the display element such as an organic light-emitting diode OLED (see FIG. 5). Each of the plurality of pixels P may emit light of, for example, red, green, blue, or white through the organic light-emitting diode OLED (see FIG. 5).

A second substrate 300 may be provided on an upper portion of the first substrate 110. The second substrate 300 may be disposed opposite the first substrate 110 with components therebetween, the components being formed on the first substrate 110.

The second substrate 300 may be bonded to the first substrate 110 through a sealing member 400 disposed in the peripheral area PA to surround the periphery of the display area DA, thereby sealing the display area DA from the outside and preventing display elements such as the organic light-emitting diode OLED (see FIG. 5) from being exposed to external air and moisture. The sealing member 400 may be provided, for example, with frit.

In an embodiment, the display area DA may be covered by a thin film encapsulation layer (not shown), instead of the second substrate 300, to protect the display elements from external air or moisture. The thin film encapsulation layer may be integrally provided to correspond to the entire surface of the display area DA, and may be partially disposed on the peripheral area PA. The thin film encapsulation layer may be provided to cover some or all of a first scan driving circuit 111, a first light-emitting driving circuit 115, a second scan driving circuit 121, a first power supply line 160, and a common voltage supply line 171, which will be described below.

The organic light-emitting diode OLED (see FIG. 5) is vulnerable to external factors such as moisture and oxygen, so the reliability of the display device 1 may be improved by sealing the organic light-emitting diode OLED (see FIG. 5). When the thin film encapsulation layer is provided instead of the second substrate 300, the thickness of the display device 1 may be reduced and flexibility may be improved.

Each of the plurality of pixels P may be electrically connected to peripheral circuits disposed in the peripheral area PA. The first scan driving circuit 111, the first light-emitting driving circuit 115, the second scan driving circuit 121, a data driving circuit 152, the first power supply line 160, and the common voltage supply line 171 may be disposed in the peripheral area PA.

The first scan driving circuit 111 may provide a scan signal to each of the plurality of pixels P through a scan line SL. The first light-emitting driving circuit 115 may provide an emission control signal to each pixel P through an emission control line EL. The second scan driving circuit 121 may be disposed parallel to the first scan driving circuit 111 with the display area DA therebetween. Some of the pixels P disposed in the display area DA may be electrically connected to the first scan driving circuit 111 and the rest may be connected to the second scan driving circuit 121. In an embodiment, a second emission driving circuit (not shown) may be disposed in parallel to the first light-emitting driving circuit 115 with the display area DA therebetween.

The first light-emitting driving circuit 115 may be disposed in the peripheral area PA spaced apart from the first scan driving circuit 111 in the x direction. In an embodiment, the first light-emitting driving circuit 115 may be disposed alternately with the first scan driving circuit 111 in the y-direction.

The terminal 140 may be disposed on one side of the first substrate 110. The terminal 140 may not be covered by an insulating layer but may be exposed and thus may be electrically connected to a printed circuit board PCB. A terminal PCB-P of the printed circuit board PCB may be electrically connected to the terminal 140 of the display panel 10. The printed circuit board PCB is configured to provide signals or power of a controller (not shown) to the display panel 10.

Control signals generated by the controller may be provided to each of the first scan driving circuit 111 and the second scan driving circuit 121. The controller may provide a driving voltage ELVDD and a common voltage ELVSS to the first power supply line 160 and the common voltage supply line 171, respectively, through connection wiring (not shown). The driving voltage ELVDD may be provided to each of the plurality of pixels P through a driving voltage line PL connected to the first power supply line 160, and the common voltage ELVSS may be provided to the counter electrode of each of the plurality of pixels P connected to the common voltage supply line 171.

The first power supply line 160 may include sub lines (not shown) that extend in parallel to each other in the x direction with the display area DA therebetween. The common voltage supply line 171 may partially surround the display area DA in a loop shape with one side open.

The data driving circuit 152 is electrically connected to the data line DL. The data signal of the data driving circuit 152 may be provided to each of the plurality of pixels P through a connection wire 151 connected to the terminal 140 and a data line DL connected to the connection wire 151. FIG. 2 illustrates that the data driving circuit 152 is disposed on the printed circuit board PCB. However, in an embodiment, the data driving circuit 152 may be disposed on the first substrate 110. For example, the data driving circuit 152 may be disposed between the terminal 140 and the first power supply line 160.

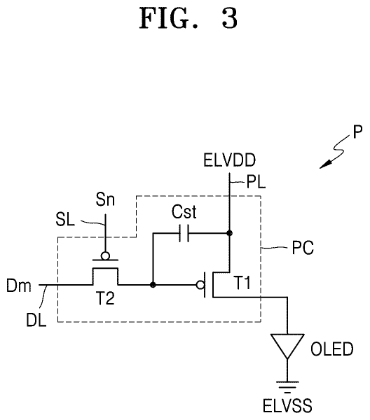

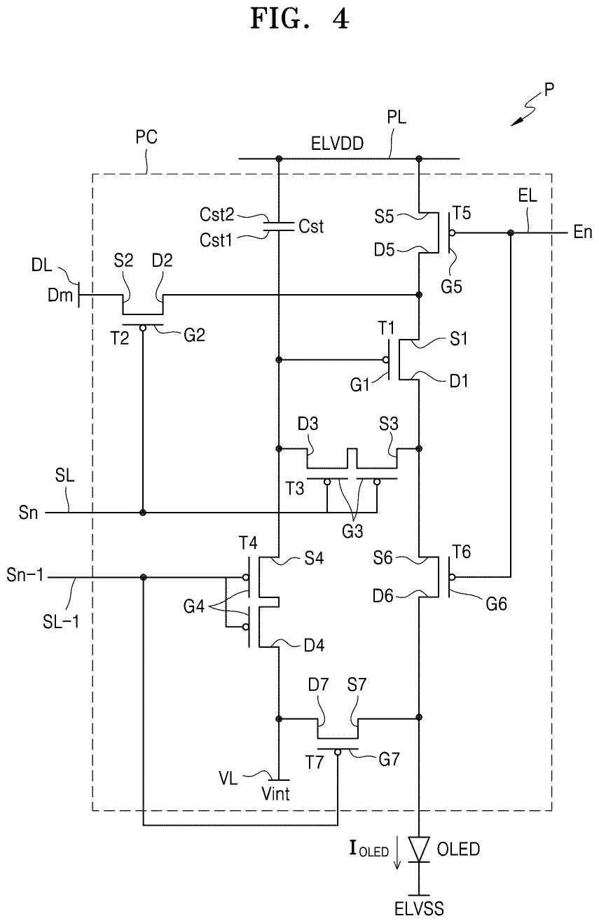

FIGS. 3 and 4 are equivalent circuit diagrams of the pixel P that may be included in the display device 1 (see FIG. 1) according to an embodiment.

Referring to FIG. 3, each of the plurality of pixels P include a pixel circuit PC connected to the scan line SL and the data line DL, and an organic light-emitting diode OLED connected to the pixel circuit PC.

The pixel circuit PC includes a driving thin film transistor T1, a switching thin film transistor T2, and a storage capacitor Cst. The switching thin film transistor T2 is connected to the scan line SL and the data line DL and is configured to provide a data signal Dm, which is input via the data line DL according to a scan signal Sn input via the scan line SL, to the driving thin film transistor T1.

The storage capacitor Cst is connected between the switching thin film transistor T2 and the driving voltage line PL and stores a voltage corresponding to the difference between the voltage received from the switching thin film transistor T2 and the driving voltage ELVDD supplied to the driving voltage line PL.

The driving thin film transistor T1 is connected between the driving voltage line PL and the organic light-emitting diode OLED, and may control the driving current flowing through the organic light-emitting diode OLED from the driving voltage line PL in response to the voltage value stored in the storage capacitor Cst. The organic light-emitting diode OLED may emit light of a certain brightness according to the driving current.

In FIG. 3, the pixel circuit PC includes two thin film transistors and one storage capacitor. However, the disclosure is not limited thereto. As shown in FIG. 4, the pixel circuit PC may include seven thin film transistors and one storage capacitor.

Referring to FIG. 4, each of the plurality of pixels P include the pixel circuit PC and an organic light-emitting diode OLED connected to the pixel circuit PC. The pixel circuit PC may include a plurality of thin film transistors and a storage capacitor. The thin film transistors and the storage capacitor may be connected to signal lines SL, SL-1, EL, and DL, an initialization voltage line VL, and the driving voltage line PL.

In FIG. 4, each pixel P is connected to the signal lines SL, SL-1, EL, and DL, the initialization voltage line VL, and the driving voltage line PL. However, the disclosure is not limited thereto. In an embodiment, at least one of the signal lines SL, SL-1, EL, and DL, the initialization voltage line VL, and the driving voltage line PL may be shared by neighboring pixels P.

The plurality of thin film transistors may include the driving thin film transistor T1, the switching thin film transistor T2, a compensation thin film transistor T3, a first initialization thin film transistor T4, an operation control thin film transistor T5, an emission control thin film transistor T6, and a second initialization thin film transistor T7.

The signal lines SL, SL-1, EL, and DL include the scan line SL that transmits the scan signal Sn, a previous scan line SL-1 that transmits a previous scan signal Sn-1 to the first initialization thin film transistor T4 and the second initialization thin film transistor T7, an emission control line EL that transmits an emission control signal En to the operation control thin film transistor T5 and the emission control thin film transistor T6, and the data line DL that intersects the scan line SL and transmits the data signal Dm. The driving voltage line PL is configured to transmit the driving voltage ELVDD to the driving thin film transistor T1 and the initialization voltage line VL is configured to transmit an initialization voltage Vint for initializing the driving thin film transistor T1 and a pixel electrode.

A driving gate electrode G1 of the driving thin film transistor T1 is connected to a first storage capacitor plate Cst1 of the storage capacitor Cst, a driving source electrode S1 of the driving thin film transistor T1 is connected to a lower driving voltage line, i.e., the driving voltage line PL, via the operation control thin film transistor T5, and a driving drain electrode D1 of the driving thin film transistor T1 is electrically connected to the pixel electrode of the organic light-emitting diode OLED via the emission control thin film transistor T6. The driving thin film transistor T1 receives the data signal Dm according to the switching operation of the switching thin film transistor T2 and supplies a driving current I_{OLED} to the organic light-emitting diode OLED.

A switching gate electrode G2 of the switching thin film transistor T2 is connected to the scan line SL, a switching source electrode S2 of the switching thin film transistor T2 is connected to the data line DL, a switching drain electrode D2 of the switching thin film transistor T2 is connected to the driving source electrode S1 of the driving thin film transistor T1 and, at the same time, is connected to the lower driving voltage line, i.e., the driving voltage line PL, via the operation control thin film transistor T5. The switching thin film transistor T2 is turned on according to the scan signal Sn received through the scan line SL and performs a switching operation for transmitting the data signal Dm transmitted through the data line DL to the driving source electrode S1 of the driving thin film transistor T1.

A compensation gate electrode G3 of the compensation thin film transistor T3 is connected to the scan line SL, a compensation source electrode S3 of the compensation thin film transistor T3 is connected to the driving drain electrode D1 of the driving thin film transistor T1 and, at the same time, is connected to the pixel electrode of the organic light-emitting diode OLED via the emission control thin film transistor T6, and a compensation drain electrode D3 of the compensation thin film transistor T3 is connected to the first storage capacitor plate Cst1 of the storage capacitor Cst, a first initialization source electrode S4 of the first initialization thin film transistor T4, and the driving gate electrode G1 of the driving thin film transistor T1. The compensation thin film transistor T3 is turned on according to the scan signal Sn received through the scan line SL to electrically connect the driving gate electrode G1 and the driving drain electrode D1 of the driving thin film transistor T1 to each other and to diode-connect the driving thin film transistor T1.

A first initialization gate electrode G4 of the first initialization thin film transistor T4 is connected to the previous scan line SL-1, a first initialization drain electrode D4 of the first initialization thin film transistor T4 is connected to a second initialization drain electrode D7 of the second initialization thin film transistor T7 and the initialization voltage line VL, and the first initialization source electrode S4 of the first initialization thin film transistor T4 is connected to the first storage capacitor plate Cst1 of the storage capacitor Cst, the compensation drain electrode D3 of the compensation thin film transistor T3, and the driving gate electrode G1 of the driving thin film transistor T1. The first initialization thin film transistor T4 is turned on according to the previous scan signal Sn-1 transmitted through the previous scan line SL-1 to transmit the initialization voltage Vint to the driving gate electrode G1 of the driving thin film transistor T1 and perform an initialization operation for initializing a voltage at the driving gate electrode G1 of the driving thin film transistor T1.

An operation control gate electrode G5 of the operation control thin film transistor T5 is connected to the emission control line EL, an operation control source electrode S5 of the operation control thin film transistor T5 is connected to the lower driving voltage line, i.e., the driving voltage line PL, and an operation control drain electrode D5 of the operation control thin film transistor T5 is connected to the driving source electrode S1 of the driving thin film transistor T1 and the switching drain electrode D2 of the switching thin film transistor T2.

An emission control gate electrode G6 of the emission control thin film transistor T6 is connected to the emission control line EL, an emission control source electrode S6 of the emission control thin film transistor T6 is connected to the driving drain electrode D1 of the driving thin film transistor T1 and the compensation source electrode S3 of the compensation thin film transistor T3, and an emission control drain electrode D6 of the emission control thin film transistor T6 is electrically connected to a second initialization source electrode S7 of the second initialization thin film transistor T7 and the pixel electrode of the organic light-emitting diode OLED.

The operation control thin film transistor T5 and the emission control thin film transistor T6 are simultaneously turned on according to the emission control signal En transmitted through the emission control line EL, and are configured to transmit the driving voltage ELVDD to the organic light-emitting diode OLED and to allow the driving current I_{OLED} to flow in the organic light-emitting diode OLED.

The second initialization gate electrode G7 of the second initialization thin film transistor T7 is connected to the previous scan line SL-1, the second initialization source electrode S7 of the second initialization thin film transistor T7 is connected to the emission control drain electrode D6 of the emission control thin film transistor T6 and the pixel electrode of the organic light-emitting diode OLED, and the second initialization drain electrode D7 of the second initialization thin film transistor T7 is connected to the first initialization drain electrode D4 of the first initialization thin film transistor T4 and the initialization voltage line VL. The second initialization thin film transistor T7 is turned on according to the previous scan signal Sn-1 transmitted through the previous scan line SL-1 to initialize the pixel electrode of the organic light-emitting diode OLED.

FIG. 4 illustrates an example in which the first initialization thin film transistor T4 and the second initialization thin film transistor T7 are connected to the previous scan line SL-1. However, the disclosure is not limited thereto. In an embodiment, the first initialization thin film transistor T4 may be connected to the previous scan line SL-1 to operate according to the previous scan signal Sn-1, and the second initialization thin film transistor T7 may be connected to a separate signal line (e.g., a post scan line) to operate according to a signal transmitted to the separate signal line.

A second storage capacitor plate Cst2 of the storage capacitor Cst is connected to the driving voltage line PL, and a counter electrode of the organic light-emitting diode OLED is connected to a common voltage, i.e., the common voltage ELVSS. Accordingly, the organic light-emitting diode OLED emits light by receiving the driving current I_{OLED} from the driving thin film transistor T1 to display images.

In FIG. 4, the compensation thin film transistor T3 and the first initialization thin film transistor T4 have dual-gate electrodes, but the compensation thin film transistor T3 and the first initialization thin film transistor T4 may each have single gate electrode.

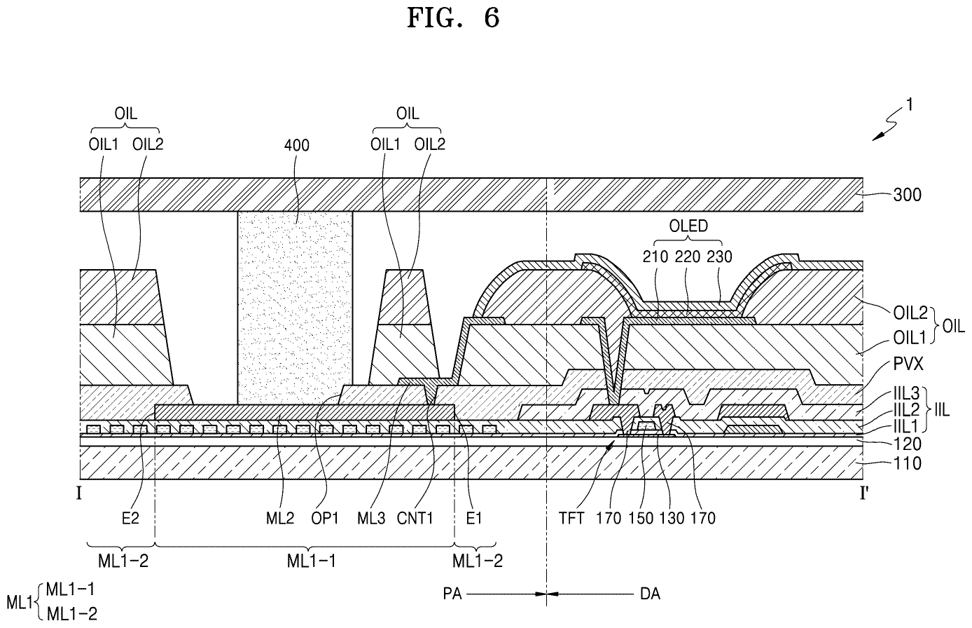

FIGS. 5 and 6 are cross-sectional views schematically illustrating a portion of the display device 1 according to an embodiment.

Referring to FIGS. 5 and 6, the display device 1 may include the first substrate 110, a thin film transistor TFT, an inorganic insulating layer IIL, a first metal layer ML1, a second metal layer ML2, an inorganic protective layer PVX, an organic insulating layer OIL, the organic light-emitting diode OLED, a third metal layer ML3, the sealing member 400, and the second substrate 300.

The first substrate 110 may be formed of various materials such as glass, metal, or plastic. The thin film transistor TFT may be disposed on the first substrate 110 so as to overlap the display area DA. The thin film transistors TFT includes a semiconductor layer 130 including amorphous silicon, polycrystalline silicon or an organic semiconductor material, a gate electrode 150 and a source/drain electrodes 170.

A buffer layer 120 formed of silicon oxide, silicon nitride, or the like may be disposed on the first substrate 110 to flatten the surface of the first substrate 110 or prevent impurities, etc. from penetrating into the semiconductor layer 130, and the semiconductor layer 130 may be disposed on the buffer layer 120. In this state, the buffer layer 120 may be disposed throughout the entire display area DA and peripheral area PA. The inorganic insulating layer IIL containing an inorganic material may be disposed on the buffer layer 120. The inorganic insulating layer IIL may include a gate insulating film IIL1, a first interlayer insulating film IIL2, and a second interlayer insulating film IIL3.

The gate electrode 150 is disposed on the upper portion of the semiconductor layer 130, and the source/drain electrodes 170 are electrically connected according to a signal applied to the gate electrode 150. The gate electrode 150 may be formed as a single layer or multiple layers using one or more materials selected from the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), taking into consideration adhesion to adjacent layers, surface flatness of the laminated layers, and processability. In order to secure insulation between the semiconductor layer 130 and the gate electrode 150, the gate insulating film IIL1 formed of silicon oxide and/or silicon nitride may be disposed between the semiconductor layer 130 and the gate electrode 150. In this state, the gate insulating film IIL1 may be disposed throughout the entire display area DA and peripheral area PA.

The first metal layer ML1 may be disposed on the first substrate 110 so as to overlap the peripheral area PA. In detail, the first metal layer ML1 may be disposed on the gate insulating film IIL1. A plurality of metal patterns may be formed in the first metal layer ML1. For example, a plurality of openings may be disposed in the first metal layer ML1. The first metal layer ML1 and the gate electrode 150 are disposed on a same layer and may include a same material. The first metal layer ML1 may be electrically connected with the gate electrode 150. The first metal layer ML1 is connected to the scan line SL (see FIG. 3) and may receive the scan signal Sn (see FIG. 3). The first metal layer ML1 may transmit the scan signal Sn (see FIG. 3) to the gate electrode 150.

The first interlayer insulating film IIL2 may be disposed on the gate insulating film IIL1. The first interlayer insulating film IIL2 may be disposed throughout the entire display area DA and peripheral area PA. The first interlayer insulating film IIL2 may cover the gate electrode 150 and the first metal layer ML1. The first interlayer insulating film IIL2 may be formed as a single layer or as multiple layers using a material such as silicon oxide or silicon nitride.

The source/drain electrodes 170 are disposed on the upper portion of the first interlayer insulating film IIL2. The source/drain electrodes 170 are electrically connected to the semiconductor layer 130 through contact holes formed in the first interlayer insulating film IIL2 and the gate insulating film IIL1. The source/drain electrodes 170 may be formed as a single layer or multiple layers using one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), taking conductivity, etc. into consideration.

The second metal layer ML2 may be disposed on the first interlayer insulating film IIL2 so as to overlap the first metal layer ML1. The second metal layer ML2 is disposed in a same layer as the source/drain electrodes 170 and may contain a same material. The second metal layer ML2 may be electrically connected to the common voltage supply line 171 (see FIG. 2). The second metal layer ML2 may receive the common voltage ELVSS (see FIG. 3) from the common voltage supply line 171 (see FIG. 2).

The second interlayer insulating film IIL3 may be disposed on the first interlayer insulating film IIL2. The second interlayer insulating film IIL3 may cover the source/drain electrodes 170 and the second metal layer ML2. The second interlayer insulating film IIL3 may protect the thin film transistor TFT. The second interlayer insulating film IIL3 may be disposed in the display area DA. The second interlayer insulating film IIL3 may not cover the second metal layer ML2 and be spaced apart from the second metal layer ML2. The second interlayer insulating film IIL3 may be formed of an inorganic material such as silicon oxide, silicon nitride, or silicon oxynitride. In FIGS. 5 and 6, the second interlayer insulating film IIL3 is depicted as a single layer, but various modifications are possible, such as having a multilayer structure.

The inorganic protective layer PVX may be disposed on the inorganic insulating layer IIL. In detail, the inorganic protective layer PVX may be disposed on the first interlayer insulating film IIL2 and the second interlayer insulating film IIL3. The inorganic protective layer PVX may be disposed throughout the entire display area DA and peripheral area PA. The inorganic protective layer PVX may include a first opening OP1 exposing a portion of the second metal layer ML2. The central portion of the second metal layer ML2 may be exposed by the inorganic protective layer PVX. The inorganic protective layer PVX may cover end portions E1 and E2 of the second metal layer (ML2). As shown in FIGS. 5 and 6, the inorganic protective layer PVX may cover one end portion E1 and the other end portion E2 of the second metal layer, respectively.

The inorganic insulating layer IIL and the inorganic protective layer PVX may be provided as a single-film or multi-film structure of silicon oxide (SiOx) and silicon nitride (SiNx). For example, the first interlayer insulating film IIL2 may include a silicon oxide (SiOx) material and the inorganic protective layer PVX may include a silicon nitride (SiNx) material.

An organic insulating layer OIL may be disposed on the inorganic protective layer PVX. The organic insulating layer OIL may cover at least a portion of the inorganic protective layer PVX. In the display area DA, the organic insulating layer OIL may perform the function of a planarizing film to planarize a uneven surface formed by the inorganic insulating layer IIL and inorganic protective layer PVX covering the thin film transistor TFT. The organic insulating layer OIL may be formed of, for example, an acrylic organic material or benzocyclobutene (BCB). An organic insulating layer OIL may be disposed in the display area DA and the peripheral area PA. The organic insulating layer OIL may not cover the second metal layer ML2 and be spaced apart from the second metal layer ML2. Accordingly, a phenomenon of heat transferred to the second metal layer ML2 being conducted to the organic insulating layer OIL may be reduced.

The first metal layer ML1 may include a first-1 metal layer portion ML1-1 that overlaps the second metal layer ML2 and a first-2 metal layer portion ML1-2 that does not overlap the second metal layer ML2. In a plan view, the first-2 metal layer portion ML1-2 may be spaced apart from the second metal layer ML2. As shown in FIGS. 5 and 6, in a structure in which the second metal layer ML2 is disposed on a central portion of the first metal layer ML1, the first-2metal layer portion ML1-2 may be disposed on one side and the other side of the first-1 metal layer portion ML1-1, respectively.

The first-2 metal layer portion ML1-2 may overlap the inorganic protective layer PVX. An inorganic protective layer PVX may be disposed on the first-2 metal layer portion ML1-2. In this structure, the first-1 metal layer portion ML1-1 may be protected from external foreign substances by the second metal layer ML2 and the inorganic protective layer PVX. Additionally, the first-2 metal layer portion ML1-2 may be protected from external foreign substances by the inorganic protective layer PVX. For example, the external foreign substances may include moisture.

An organic light-emitting diode OLED may include a pixel electrode 210, an intermediate layer 220, and a counter electrode 230. The pixel electrode 210 may be disposed on the inorganic protective layer PVX so as to overlap the display area DA. The organic insulating layer OIL may include a first organic insulating layer OIL1 and a second organic insulating layer OIL2 disposed on the first organic insulating layer OIL1. The organic insulating layer OIL (in detail, the first organic insulating layer OIL1) may be disposed between the inorganic protective layer PVX and the counter electrode 230. In detail, the pixel electrode 210 may be disposed between the first organic insulating layer OIL1 and the second organic insulating layer OIL2. The pixel electrode 210 may be electrically connected to the thin film transistor TFT. The pixel electrode 210 may be in contact with at least one of the source/drain electrodes 170 of the thin film transistor TFT through an opening formed in the second interlayer insulating film IIL3, the inorganic protective layer PVX, and the first organic insulating layer OIL1.

The pixel electrode 210 may be formed as a (semi)transparent electrode or a reflective electrode. When formed as the (semi)transparent electrode, the pixel electrode 210 may be formed of, for example, ITO, IZO, ZnO, In2O3, IGO or AZO. When formed as the reflective electrode, the pixel electrode 210 may have a reflective film formed of Ag, Mg, Al, Pt, Pd, Au, Ni, Nd, Ir, Cr, and/or compounds thereof, and a layer formed of ITO, IZO, ZnO, In2O3, IGO, or AZO. Obviously, the disclosure is not limited thereto, and may be formed of various materials, and its structure may also be modified in various ways such as being single-layered or multi-layered.

In the display area DA, the second organic insulating layer OIL2 serves as a pixel-defining film and defines pixels by having an opening corresponding to each subpixel, that is, an opening that exposes at least the central portion of the pixel electrode 210. In addition, as shown in FIGS. 5 and 6, the second organic insulating layer OIL2 prevents arcs and the like from occurring at an end portion of the pixel electrode 210 by increasing the distance between the end portion of the pixel electrode 210 and the counter electrode 230 above the pixel electrode 210. The second organic insulating layer OIL2 may be formed of an organic material such as polyimide.

The intermediate layer 220 contains a light-emitting material and may be disposed on the pixel electrode 210. The intermediate layer 220 may be accommodated in the opening disposed in the second organic insulating layer OIL2. The intermediate layer 220 may include a low molecular weight or high molecular weight material. When low-molecular-weight materials are included, layers such as a hole injection layer, a hole transport layer, an emission layer, an electron transport layer, and an electron injection layer may be formed in a single or multi-layered structure. Usable organic materials may include various substances such as copper phthalocyanine (CuPc), N,N′-Di(naphthalene-1-yl)-N,N′-diphenyl-benzidine (NPB), and tris(8-hydroxyquinoline)aluminum (Alq₃). These layers may be formed by methods such as vacuum deposition.

When the intermediate layer 220 includes a polymer material, the intermediate layer 220 may usually have a structure including the hole transport layer and the emission layer. In this state, PEDOT is used as the hole transport layer, and polymer materials such as PPV (poly-phenylenevinylene) and polyfluorene are used as the light-emitting layer, and these may be formed by screen printing, inkjet printing, or laser induced thermal imaging (LITI).

Obviously, the intermediate layer 220 is not necessarily limited thereto and may have any one of various structures.

The counter electrode 230 may be disposed on the intermediate layer 220. The counter electrode 230 is disposed above the display area DA, and may be disposed to cover the display area DA as shown in FIGS. 5 and 6. That is, the counter electrode 230 may be formed integrally in a plurality of organic light-emitting diodes OLED and correspond to a plurality of pixel electrodes 210. The counter electrode 230 may be formed as a (semi)transparent electrode or a reflective electrode. When the counter electrode 230 is formed as the (semi)transparent electrode, the counter electrode 230 may have a layer formed of a metal having a small work function, i.e., Li, Ca, LiF/Ca, LiF/Al, Al, Ag, Mg, and/or compounds thereof, and a (semi)transparent conductive layer such as ITO, IZO, ZnO, or In2O3. When the counter electrode 230 is formed as the reflective electrode, the counter electrode 230 may have a layer formed of Li, Ca, LiF/Ca, LiF/Al, Al, Ag, Mg, and/or compounds thereof. Obviously, the configuration and material of the counter electrode 230 are not limited thereto and various modifications are possible.

The third metal layer ML3 is disposed on the inorganic protective layer PVX and the first organic insulating layer OIL1 and may electrically connect the counter electrode 230 to the second metal layer ML2. In detail, one end portion of the third metal layer ML3 may be disposed on the inorganic protective layer PVX so as to overlap the second metal layer ML2, and the other end portion of the third metal layer ML3 may be disposed between the first organic insulating layer OIL1 and the second organic insulating layer OIL2. The third metal layer ML3 includes a same material as the pixel electrode 210, and at least a portion of the third metal layer ML3 may be disposed in a same layer as the pixel electrode 210. The inorganic protective layer PVX may include a first contact hole CNT1 exposing a portion of the second metal layer ML2 and disposed so as to be spaced apart from the first opening OP1. The first contact hole CNT1 may be disposed in the peripheral area PA. The first contact hole CNT1 may be disposed closer to the display area DA than the first opening OP1. The third metal layer ML3 may come into contact with the second metal layer ML2 through the first contact hole CNT1.

In the peripheral area PA, the organic insulating layer OIL may be disposed on the inorganic protective layer PVX. The organic insulating layer OIL may cover the end portion of the third metal layer ML3. In the peripheral area PA, the organic insulating layer OIL may be disposed so as to be spaced apart from the first opening OP1 of the inorganic protective layer PVX. In the peripheral area PA, the organic insulating layer OIL may include an opening disposed in an area corresponding to the first opening OP1. The sealing member 400 may be disposed in the area corresponding to the opening OP1 of the inorganic protective layer PVX and the opening of the organic insulating layer OIL.

The second substrate 300 may be disposed on the first substrate 110. The second substrate 300 may be disposed on the organic light-emitting diode OLED, the first metal layer ML1, the second metal layer ML2, the third metal layer ML3, and the inorganic protective layer PVX. The second substrate 300 may be disposed throughout the entire display area DA and peripheral area PA. The second substrate 300 may face the first substrate 110 and may be formed of various materials such as glass, metal, or plastic.

The sealing member 400 may be disposed on the inorganic protective layer PVX so as to cover the first opening OP1. The second substrate 300 is disposed on the sealing member 400, and the second substrate 300 may be supported by the sealing member 400. The first substrate 110 and the second substrate 300 may be joined through the sealing member 400. The sealing member 400 may include frit or epoxy, but obviously, the disclosure is not limited thereto.

When bonding the first substrate 110 and the second substrate 300 using the sealing member 400, a process of curing the sealing member 400 by irradiating it with UV light or a laser beam, etc., may be performed. In detail, the UV light or laser beam, etc. may be passed through the second substrate 300 and irradiated onto the sealing member 400.

The sealing member 400 may be in direct contact with the second metal layer ML2. Accordingly, since the heat transferred to the second metal layer ML2 is conducted to the sealing member 400, the bonding strength between the sealing member 400 and the second metal layer ML2 may be strengthened. In addition, the hardness of the sealing member 400 may be strengthened due to the contact between the second metal layer ML2 including a metal material and the sealing member 400. Also, by using the second metal layer ML2 under the sealing member 400 to reflect UV light or laser beams that have passed through the sealing member 400 so that the UV light or laser beams are directed back toward the sealing member 400, the irradiation efficiency of the UV light or laser beams may be enhanced.

As illustrated in FIG. 5, the second metal layer ML2 may be covered by the inorganic protective layer PVX, and the sealing member 400. The sealing member 400 may cover an end portion of the inorganic protective layer PVX where the first opening OP1 is formed. Therefore, the phenomenon of the second metal layer ML2 being exposed and corroded may be reduced. However, this is only an example, and, depending on the required design, a portion of the upper surface of the second metal layer ML2 may be exposed from the sealing member 400, as illustrated in FIG. 6.

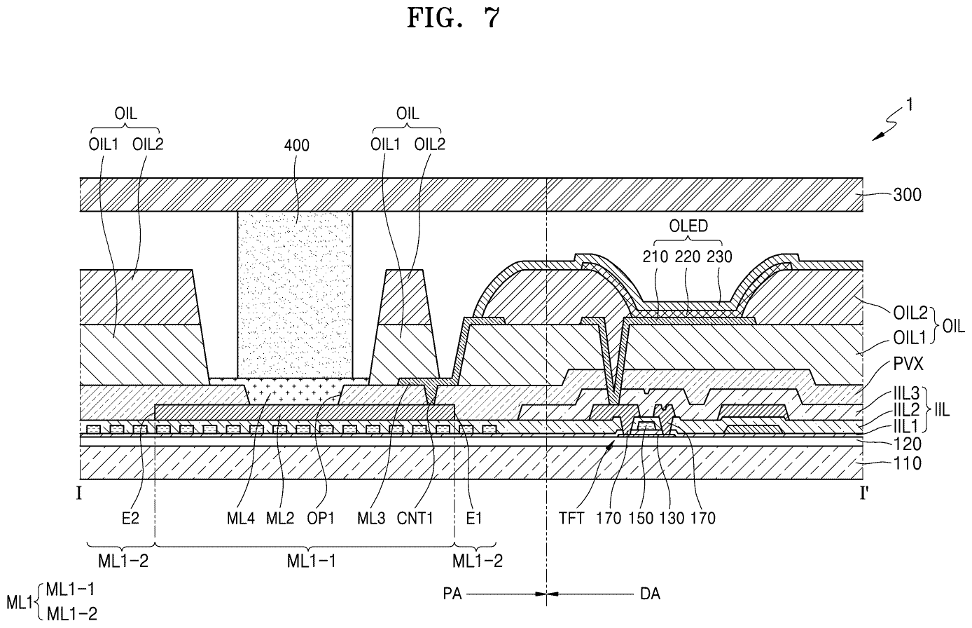

FIG. 7 is a cross-sectional view schematically illustrating a portion of the display device 1 according to an embodiment.

In FIG. 7, like reference numerals in FIGS. 5 and 6 denote like elements, and redundant descriptions thereof are omitted.

Referring to FIG. 7, the display device 1 may include the first substrate 110, the thin film transistor TFT, the inorganic insulating layer IIL, the first metal layer ML1, the second metal layer ML2, the inorganic protective layer PVX, the organic insulating layer OIL, the organic light-emitting diode OLED, the third metal layer ML3, the sealing member 400, and the second substrate 300.

The thin film transistor TFT may be disposed on the first substrate 110 so as to overlap a display area DA. The thin film transistor TFT may include the semiconductor layer 130, the gate electrode 150, and source/drain electrodes 170. A buffer layer 120 may be disposed on the first substrate 110, and the semiconductor layer 130 may be disposed on the buffer layer 120. The gate electrode 150 may be disposed on top of the semiconductor layer 130. The gate insulating film IIL1 may be disposed between the semiconductor layer 130 and the gate electrode 150.

The first metal layer ML1 may be disposed on the first substrate 110 in the peripheral area PA. In detail, the first metal layer ML1 may be disposed on the gate insulating film IIL1. The first interlayer insulating film IIL2 may be disposed on the gate insulating film IIL1. The first interlayer insulating film IIL2 may cover the gate electrode 150 and the first metal layer ML1. Source/drain electrodes 170 are disposed on the upper portion of the first interlayer insulating film IIL2. The second metal layer ML2 may be disposed on the first interlayer insulating film IIL2 so as to overlap the first metal layer ML1. The second interlayer insulating film IIL3 may be disposed on the first interlayer insulating film IIL2. The second interlayer insulating film IIL3 may cover the source/drain electrodes 170.

The inorganic protective layer PVX may be disposed on the inorganic insulating layer IIL. In detail, the inorganic protective layer PVX may be disposed on the first interlayer insulating film IIL2 and the second interlayer insulating film IIL3. The inorganic protective layer PVX may be disposed throughout the entire display area DA and peripheral area PA. The inorganic protective layer PVX may include the first opening OP1 exposing a portion of the second metal layer ML2. The central portion of the second metal layer ML2 may be exposed by the inorganic protective layer PVX. The inorganic protective layer PVX may cover end portions E1 and E2 of the second metal layer ML2. As shown in FIG. 7, the inorganic protective layer PVX may cover one end portion E1 and the other end portion E2 of the second metal layer, respectively.

An organic insulating layer OIL may be disposed on the inorganic protective layer PVX. The organic insulating layer OIL may cover at least a portion of the inorganic protective layer PVX. The organic insulating layer OIL may not contact the second metal layer ML2 and be separated from the second metal layer ML2. The organic insulating layer OIL may include the first organic insulating layer OIL1 and the second organic insulating layer OIL2 disposed on the first organic insulating layer OIL1.

The first metal layer ML1 may include the first-1 metal layer portion ML1-1 that overlaps the second metal layer ML2, and the first-2 metal layer portion ML1-2 that does not overlap the second metal layer ML2. The first-2 metal layer portion ML1-2 may overlap the inorganic protective layer PVX.

An organic light-emitting diode OLED may include the pixel electrode 210, an intermediate layer 220, and the counter electrode 230. The pixel electrode 210 may be disposed on the inorganic protective layer PVX so as to overlap the display area DA. The organic insulating layer OIL may include the first organic insulating layer OIL1 and the second organic insulating layer OIL2 disposed on the first organic insulating layer OIL1. An organic insulating layer OIL (in detail, the first organic insulating layer OIL1) may be disposed between the inorganic protective layer PVX and the counter electrode 230. In detail, the pixel electrode 210 may be disposed between the first organic insulating layer OIL1 and the second organic insulating layer OIL2. The pixel electrode 210 may be electrically connected to the thin film transistor TFT. The pixel electrode 210 may be in contact with at least one of the source/drain electrodes 170 of the thin film transistor TFT through an opening formed in the second interlayer insulating film IIL3, the inorganic protective layer PVX, and the first organic insulating layer OIL1.

The counter electrode 230 may be disposed on the intermediate layer 220. The counter electrode 230 is disposed above the display area DA and may be disposed to cover the display area DA as shown in FIG. 7. That is, the counter electrode 230 may be formed integrally in the plurality of organic light-emitting diodes OLED and correspond to the plurality of pixel electrodes 210.

The third metal layer ML3 is disposed on the inorganic protective layer PVX and the first organic insulating layer OIL1 and may electrically connect the counter electrode 230 to the second metal layer ML2. In detail, one end portion of the third metal layer ML3 may be disposed on the inorganic protective layer PVX so as to overlap the second metal layer ML2, and the other end portion of the third metal layer ML3 may be disposed between the first organic insulating layer OIL1 and the second organic insulating layer OIL2. The third metal layer ML3 includes a same material as the pixel electrode 210, and at least a portion of the third metal layer ML3 may be disposed in a same layer as the pixel electrode 210.

In the peripheral area PA, the organic insulating layer OIL may be disposed on the inorganic protective layer PVX. The organic insulating layer OIL may cover the end portion of the third metal layer ML3. In the peripheral area PA, the organic insulating layer OIL may be disposed so as to be spaced apart from the first opening OP1 of the inorganic protective layer PVX. In the peripheral area PA, the organic insulating layer OIL may include an opening disposed in an area corresponding to the first opening OP1. A sealing member 400 may be disposed in the opening of the organic insulating layer OIL.

The fourth metal layer ML4 may be disposed on the inorganic protective layer PVX in the peripheral area PA. At least a portion of the fourth metal layer ML4 may be disposed in the first opening OP1. The fourth metal layer ML4 is disposed between the organic insulating layer OIL and may be in contact with the organic insulating layer OIL. The fourth metal layer ML4 may come into contact with the second metal layer ML2 through the first opening OP1. The fourth metal layer ML4 may cover the upper surface of the second metal layer ML2 exposed from the inorganic protective layer PVX through the first opening OP1. The second metal layer ML2 may be sealed by the inorganic protective layer PVX and the fourth metal layer ML4. In this structure, the second metal layer ML2 may be protected from external foreign substances by the first interlayer insulating film IIL2, the inorganic protective layer PVX, and the fourth metal layer ML4. Although not shown in FIG. 7, the fourth metal layer ML4 may include a same material as the separate conductive layer disposed between the inorganic protective layer PVX and the organic insulating layer OIL in the display area DA.

The second substrate 300 may be disposed on the first substrate 110. The sealing member 400 may be disposed on the fourth metal layer ML4. The sealing member 400 may be in direct contact with the fourth metal layer ML4. The second substrate 300 is disposed on the sealing member 400, and the second substrate 300 may be supported by the sealing member 400. The first substrate 110 and the second substrate 300 may be joined through the sealing member 400. The sealing member 400 may include frit or epoxy, but obviously, the disclosure is not limited thereto.

The sealing member 400 may be in direct contact with the fourth metal layer ML4. Accordingly, since heat transferred to the fourth metal layer ML4 is conducted to the sealing member 400, the bonding strength between the sealing member 400 and the fourth metal layer ML4 may be strengthened. In addition, the hardness of the sealing member 400 may be strengthened due to the contact between the fourth metal layer ML4 including a metal material and the sealing member 400. Also, by using the fourth metal layer ML4 under the sealing member 400 to reflect UV light or laser beams that have passed through the sealing member 400 so that the UV light or laser beams are directed back toward the sealing member 400, the irradiation efficiency of the UV light or laser beams may be enhanced.

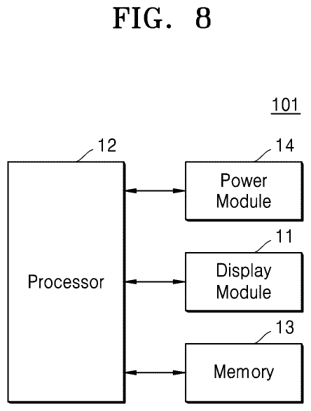

FIG. 8 is a block diagram of an electronic device 101 according to an embodiment.

Referring to FIG. 8, an electronic device 101 according to one embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information necessary for the operation of the processor 12 or display module 11 may be stored in the memory 13. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power required for the operation of the electronic device 101.

At least one of the components of the following electronic device 101 may be included in the display device 1 (see FIG. 1). Additionally, some of the individual modules functionally included within a single module may be included within the display device 1 (see FIG. 1), while others may be provided separately from the display device 1 (see FIG. 1). For example, the display device 1 (see FIG. 1) may include the display module 11, and the processor 12, memory 13, and power module 14 may be provided in the form of other devices within the electronic device 101 other than the display device.

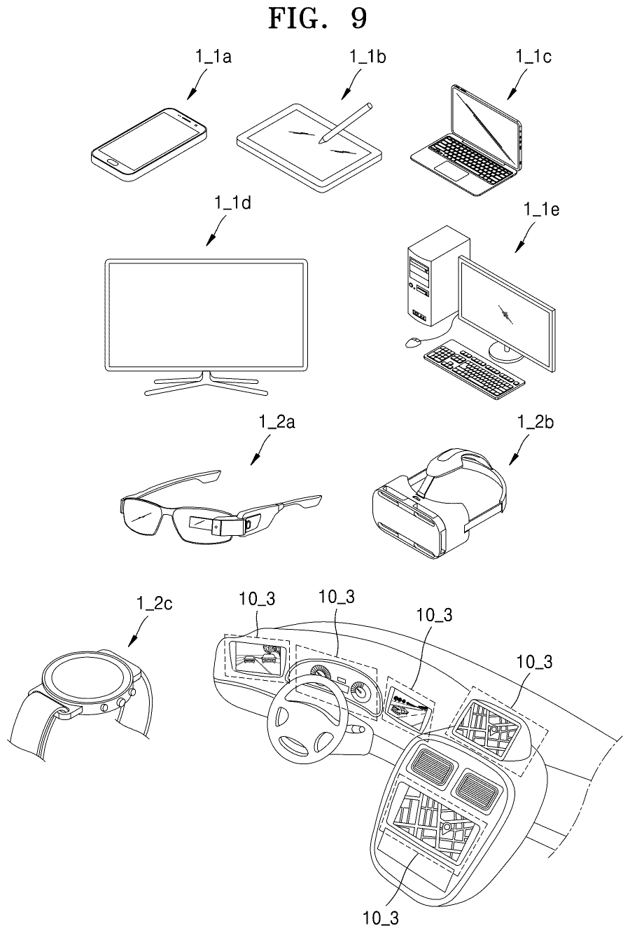

FIG. 9 is a perspective view schematically illustrating an electronic device according to an embodiment.

Referring to FIG. 9, various electronic devices to which display devices 1 (see FIG. 1) according to embodiments are applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 1_2a, a head mounted display 1_2b, and a smart watch 1_2c, and vehicle electronic devices 10_3 including display modules such as a center information display (CID) and a room mirror display disposed on a dashboard, center fascia, and dashboard of an automobile.

According to the embodiments, the durability of a display device may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a first substrate including a display area and a peripheral area;
a thin film transistor disposed on the first substrate in the display area and including a semiconductor layer and a gate electrode;
a first metal layer disposed on the first substrate in the peripheral area;
a first interlayer insulating film covering the gate electrode and the first metal layer;
a second metal layer disposed on the first interlayer insulating film so as to overlap the first metal layer;
an inorganic protective layer disposed on the first interlayer insulating film so as to cover an end portion of the second metal layer and including a first opening exposing a portion of the second metal layer; and
a sealing member disposed on the inorganic protective layer so as to overlap the first opening.

2. The display device of claim 1, wherein the first metal layer includes a first-1 metal layer portion that overlaps the second metal layer, and a first-2 metal layer portion that does not overlap the second metal layer, and
wherein the first-2 metal layer portion overlaps the inorganic protective layer.

3. The display device of claim 1, wherein the sealing member is in direct contact with the second metal layer.

4. The display device of claim 3, wherein the second metal layer is sealed by the inorganic protective layer and the sealing member.

5. The display device of claim 1, further comprising:
an organic light-emitting element including a pixel electrode disposed on the inorganic protective layer so as to overlap the display area and electrically connected to the thin film transistor, an intermediate layer disposed on the pixel electrode, and a counter electrode disposed on the intermediate layer; and
a third metal layer disposed on the inorganic protective layer and electrically connecting the counter electrode to the second metal layer.

6. The display device of claim 5, wherein the inorganic protective layer further includes a first contact hole that is spaced apart from the first opening and exposes a portion of the second metal layer, and
wherein the third metal layer is in contact with the second metal layer through the first contact hole.

7. The display device of claim 5, further comprising an organic insulating layer disposed between the inorganic protective layer and the counter electrode,
wherein the organic insulating layer is spaced apart from the second metal layer.

8. The display device of claim 1, further comprising a fourth metal layer disposed on the inorganic protective layer,
wherein at least a portion of the fourth metal layer is accommodated in the first opening and is in contact with the second metal layer.

9. The display device of claim 7, wherein the sealing member is in direct contact with the fourth metal layer.

10. The display device of claim 1, wherein the first metal layer and the gate electrode are disposed in a same layer and include a same material.

11. An electronic device comprising:
a first substrate including a display area and a peripheral area;
a thin film transistor disposed on the first substrate in the display area and including a semiconductor layer and a gate electrode;
a first metal layer disposed on the first substrate in the peripheral area;
a first interlayer insulating film covering the gate electrode and the first metal layer;
a second metal layer disposed on the first interlayer insulating film so as to overlap the first metal layer;
an inorganic protective layer disposed on the first interlayer insulating film and including a first opening exposing a portion of the second metal layer; and
a sealing member disposed on the inorganic protective layer so as to overlap the first opening,
wherein the first metal layer includes a first-1 metal layer portion that overlaps the second metal layer and a first-2 metal layer portion that does not overlap the second metal layer, and
wherein the first-2 metal layer portion overlaps the inorganic protective layer.

12. The electronic device of claim 11, wherein the inorganic protective layer covers an end portion of the second metal layer.

13. The electronic device of claim 11, wherein the sealing member is in direct contact with the second metal layer.

14. The electronic device of claim 13, wherein the second metal layer is sealed by the inorganic protective layer and the sealing member.

15. The electronic device of claim 11, further comprising:
an organic light-emitting element including a pixel electrode disposed on the inorganic protective layer so as to overlap the display area and electrically connected to the thin film transistor, an intermediate layer disposed on the pixel electrode, and a counter electrode disposed on the intermediate layer; and
a third metal layer disposed on the inorganic protective layer and electrically connecting the counter electrode to the second metal layer.

16. The electronic device of claim 15, wherein the inorganic protective layer further includes a first contact hole that is spaced apart from the first opening and exposes a portion of the second metal layer, and
wherein the third metal layer is in contact with the second metal layer through the first contact hole.

17. The electronic device of claim 15, further comprising an organic insulating layer disposed between the inorganic protective layer and the counter electrode,
wherein the organic insulating layer is spaced apart from the second metal layer.

18. The electronic device of claim 11, further comprising a fourth metal layer disposed on the inorganic protective layer,
wherein at least a portion of the fourth metal layer is accommodated in the first opening and is in contact with the second metal layer.

19. The electronic device of claim 17, wherein the sealing member is in direct contact with the fourth metal layer.

20. The electronic device of claim 11, wherein the first metal layer and the gate electrode are disposed in a same layer and include a same material.
